(19) United States
(12) Patent Application Publication
(10) Pub. No.: US 2002/0102785 A1
(43) Pub. Date: Aug. 1, 2002

(54) Method for forming shallow junctions by increasing width of photoresist and using implanting through poly film

(76) Inventors: James Ho, Hsin-Chu (TW); Chen-Hui Chung, Chu-Tung Chen (TW); Yei-Hsiung Lin, Hsin-chu City (TW)

Correspondence Address: POWELL, GOLDSTEIN, FRAZER & MURPHY LLP, P.O. BOX 97233, WASHINGTON, DC, 20090-7223, US

(21) Appl. No.: 09/770,546

(22) Filed: Jan. 26, 2001

(51) Int. Cl. H01L 21/336

(52) U.S. Cl. 438/207; 438/206

(57) ABSTRACT

A semiconductor substrate is provided, and a gate oxide layer is formed on said semiconductor substrate. Next, a poly film is deposited on said gate oxide layer, and a photo-resist is formed on the poly film for defining a length of poly gate. Then, proceeding with an ion implant of the lightly doped drain (LDD) through the poly film into the structure by the photo-resist as a mask, so as to form a lightly doped drain region in the semiconductor substrate. Next, the width of the photo-resist layer is added to be as an ion-implanted mask. The poly film is etched to form a poly gate. Then, a source/drain region is formed in the semiconductor by a ion implanting, wherein the photo-resist can be treated by thermal method or resolution enhancement lithography assisted by chemical shrink (RELACS) process to control the profile width of the photo-resist.

### BACKGROUND OF THE INVENTION

1. Field of the Invention

The present invention relates generally to a method for forming semiconductor devices process, and more particularly to a method for forming semiconductor devices having shallow junctions.

2. Description of the Prior Art

As semiconductor devices, such as Metal-Oxide-Semiconductor devices, become highly integrated, the area occupied by the devices shrinks, as well as the design rule. With advances in the semiconductor technology, the dimensions of the integrated circuit (IC) devices have shrunk to the deep sub-micron range. When the semiconductor device continuously shrinks to deep sub-micron region, some problems described below are incurred due to the process of scaling down.

Cross-sectional views of a process for forming shallow junctions in Metal-Oxide-Semiconductor (MOS) device of the known prior art are illustrated in FIG. 1A and FIG. 1B. First of all, a semiconductor substrate 110 is provided, and a gate oxide layer is formed over the semiconductor substrate 110. Then, a poly film is deposited on the gate oxide layer 120, and a photo-resist layer (not shown in the figure) is formed on the poly film, so as to define and form a poly gate electrode 130. It will proceed with an ion implant 140 of the lightly doped drain (LDD) into the semiconductor substrate by the poly gate 130 as a mask after removing the photo-resist, so as to form a lightly doped drain regions 150. Next, the spacers 160 are formed on the sidewalls of the poly gate 130 by depositing and etching back. Then, an ion implant 170 of the source/drain is carried out on the semiconductor substrate 110 by the spacers 160 as the masks. Finally, rapid thermal process ( RTP) is performed to form the source/drain regions 180 in the semiconductor substrate.

The evolution of integrated circuits has involved such that scaling down the device geometries. In deep sub-micron Metal-Oxide-Semiconductor technology, shallow junctions are required to alleviate or avoid the influences of the short channel effect. And yet, conventional shallow junctions process is very difficult to perform below 0.18 micrometer. As the channel length of the Metal-Oxide-Semiconductor is scaled down, it has become necessary to reduce the source/drain (S/D) junctions depths (in the drain extension regions near the channel) to prevent from short channel effects. According with the channel effect of the ion implantation, it will lead to be very difficult for the junction depth control after ions implant in the semiconductor device; hence, the performance of the device will be decreased. Conventionally, the ion implant energy, which reduced the projected range of the dopants, has to be reduced to reduce the junction depth. For low energy of the ions implants, it is not possible to reduce the junction depth eminently by reducing the energy of the ion implant.

In accordance with the above description, a new and improved method for fabricating the Metal-Oxide-Semiconductor device having shallow junctions is therefore necessary, so as to raise the yield and quality of the follow-up process.

### SUMMARY OF THE INVENTION

In accordance with the present invention, a method is provided for fabricating the Metal-Oxide-Semiconductor devices having shallow junctions construction that substantially overcomes drawbacks of above mentioned problems arised from the conventional methods.

Accordingly, it is a main object of the present invention to provide a method for fabricating the Metal-Oxide-Semiconductor devices having the shallow junctions, so as to form the small size and high performance elements. The method is appropriate for deep sub-micron technology to provide the Metal-Oxide-Semiconductor devices with junctions of shallow depth and of low resistance.

Another object of the present invention is to provide a method for forming shallow junctions, and the lightly doped drain through ion-implanted buffer layer can avoid channeling tails that penetrate relatively deeply into the silicon substrate or implanted junctions. The present invention can also perform the source/drain implant without forming spacers by single mask, and it decreases one step of forming mask at least. Hence, the method of the present invention can simplify step of the conventional process, and it is able to correspond to economic effect.

Still another object of the present invention is to provide a relacs material which can react with photo-resist to directly form a photo-resist-relacs (PR-relacs) having great dimension. This PR-relacs can substitute spacers as an ion-implanted mask of the source/drain regions, and it is able to control the depth of junction shallow enough and exactly. Thus, good shallow junctions integrity can be formed on silicon substrate.

Still another object of the present invention is to change the profile of the photo-resist by controlling the temperature, so as to substitute spacers as an ion implanted mask of the source /drain regions. The profile of the photo-resist is not only able to control the depth of junction shallow enough and exactly but also to simplify process, and it will reach the requirement that economize on cost.

In accordance with the present invention, a new method for forming semiconductor devices is disclosed. First of all, a semiconductor substrate is provided, and a gate oxide layer is formed on said semiconductor substrate. Next, an ion-implanted buffer layer is formed on said gate oxide layer, wherein the ion-implanted buffer layer of this present invention take poly film as a principal material for forming directly the gate to simplify process. A photo-resist is formed on the ion-implanted buffer layer for defining the length of device (such as the gate) Then, proceeding with an ion implant of the lightly doped drain (LDD) through the ion-implanted buffer layer 230 into the structure of above by the photo-resist as a mask, so as to form a lightly doped drain region in the semiconductor substrate. Then, the ion-implanted buffer layer is etched to form a gate. The photo-resist reacts with the material of relacs that has been coated over it to form a photo-resist-relacs having great dimension. Next, an ion implant of the source/drain is performed on the semiconductor substrate by the PR-relacs as a mask. Afterward, the photo-resist-relacs is removed. Furthermore, the photo-resist material can also introduce the material which is sensitive to temperature, and the profile of the photo-resist can be controlled by thermal process, that is, the photo-resist treatment by temperature controlled profile change. Then, an ion implant of the source/drain is carried out in the semiconductor substrate by the treated photo-resist as a mask. Afterward, the treated photo-resist is removed. Finally, rapid thermal process (RTP) is carried out to form the source/drain regions in the semiconductor substrate.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A and 1B show cross-sectional views illustrative of various stages in the conventional shallow junctions process of Metal-Oxide-Semiconductor devices;

FIG. 2A to 2D show cross-sectional views illustrative of various stages in the fabrication of a Metal-Oxide-Semiconductor device having shallow junctions in accordance with one embodiment of the present invention;

FIGS. 3A to 3D show cross-sectional views illustrative of various stages in the fabrication of a Metal-Oxide-Semiconductor device having shallow junctions in accordance with the other one embodiment of the present invention;

FIG. 4A show cross-sectional views illustrative of photo-resist material of the present invention at room temperature; and

FIG. 4B show cross-sectional views illustrative of photo-resist material of the present invention at temperature range which is about 150° C. to 160° C.

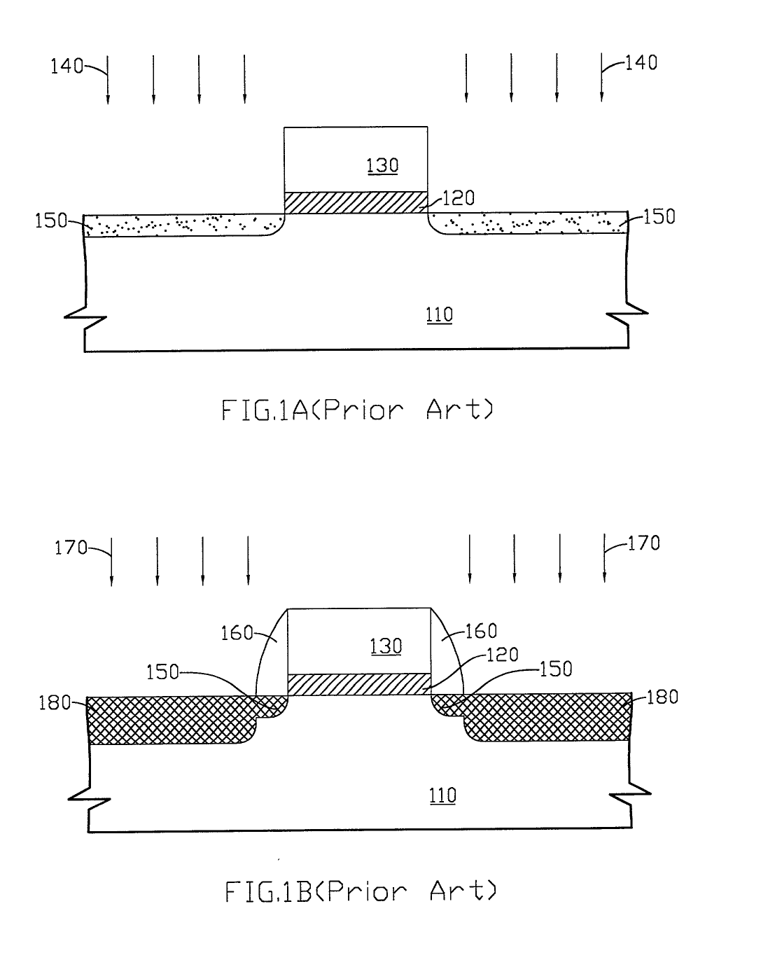

### DESCRIPTION OF THE PREFERRED EMBODIMENT

A preferred embodiment of the present invention will now be described in greater detail. Nevertheless, it should be recognized that the present invention can be practiced in a wide range of other embodiments besides those explicitly described, and the scope of the present invention is expressly not limited except as specified in the accompanying claims.

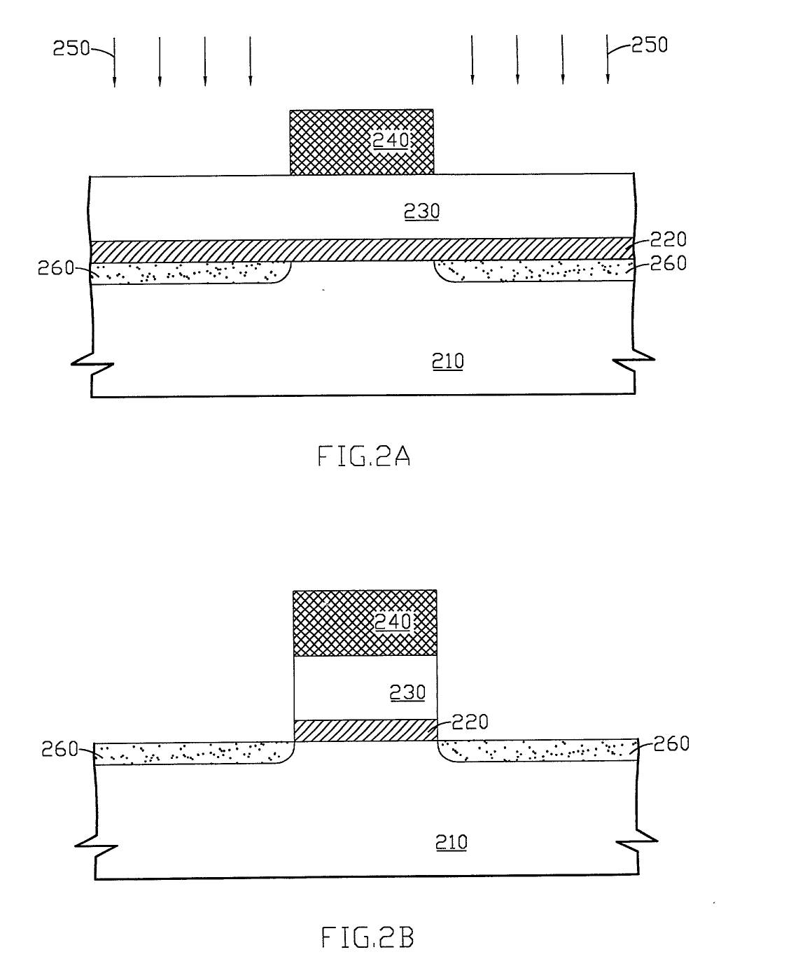

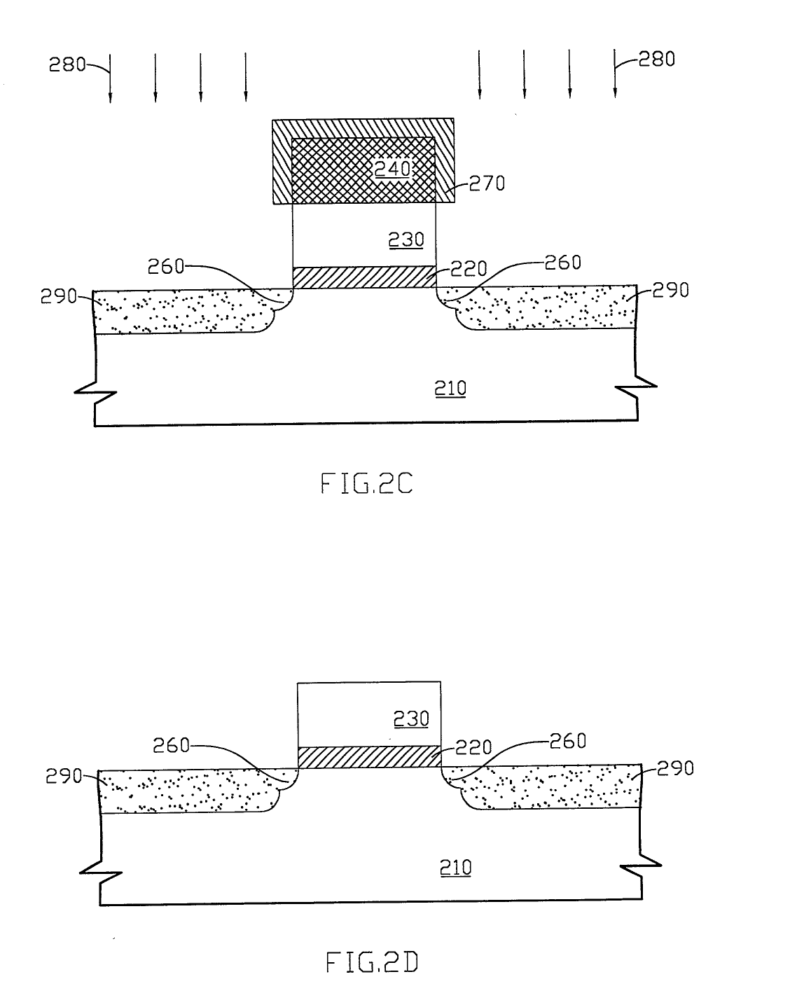

As illustrated in FIG. 2A, in this embodiment, first of all, a semiconductor substrate 210 is provided, and a thin oxide layer 220 is formed on said semiconductor substrate 210. Next, an ion-implanted buffer layer 230 is deposited on said thin oxide layer 220, and a photo-resist 240 is defined on the ion-implanted buffer layer 230, wherein the ion-implanted buffer layer 230 is such as poly. Then, proceeding with an ion implant 250 of the lightly doped drain( LDD )through the ion-implanted buffer layer 230 into the structure of above by the photo-resist 240 as a mask, so as to form a lightly doped drain region 260 in the semiconductor substrate 210.

Referring to FIG. 2A once more, in this embodiment, first of all, a semiconductor substrate 210 is provided, and a gate oxide layer 220 is formed on said semiconductor substrate 210. Next, A poly film 230 is deposited on said gate oxide layer 220 to be as an ion-implanted buffer layer, and a photo-resist 240 is formed on the poly film 230 for defining length of a poly gate. Then, proceeding with an ion implant 250 of the lightly doped drain (LDD) through the ion-implanted buffer layer 230 into the structure of above by the photo-resist 240 as a mask, so as to form a lightly doped drain region 260 in the semiconductor substrate 210. Then, the poly film 230 is etched to form a poly gate 230, as shown in FIG. 2B.

Referring to FIG. 2C, in this embodiment, the photo-resist 240 performs relacs process to form a photo-resist-relacs 270 having great dimension, wherein the photo-resist-relacs 270 is formed by the photo-resist 240 reacts with the material of the relacs, since the above process of relacs is well known in the prior art, which are not the focus of the present invention, hence will not be described in greater details. Next, an ion implant 280 of the source/drain is performed into the semiconductor substrate 210 by the PR-relacs 270 as a mask. Afterward, the PR-relacs 270 is removed. Finally, a rapid thermal process (RTP) is carried out to form the source/drain regions 290 in the semiconductor substrate 210, as shown in FIG. 2D.

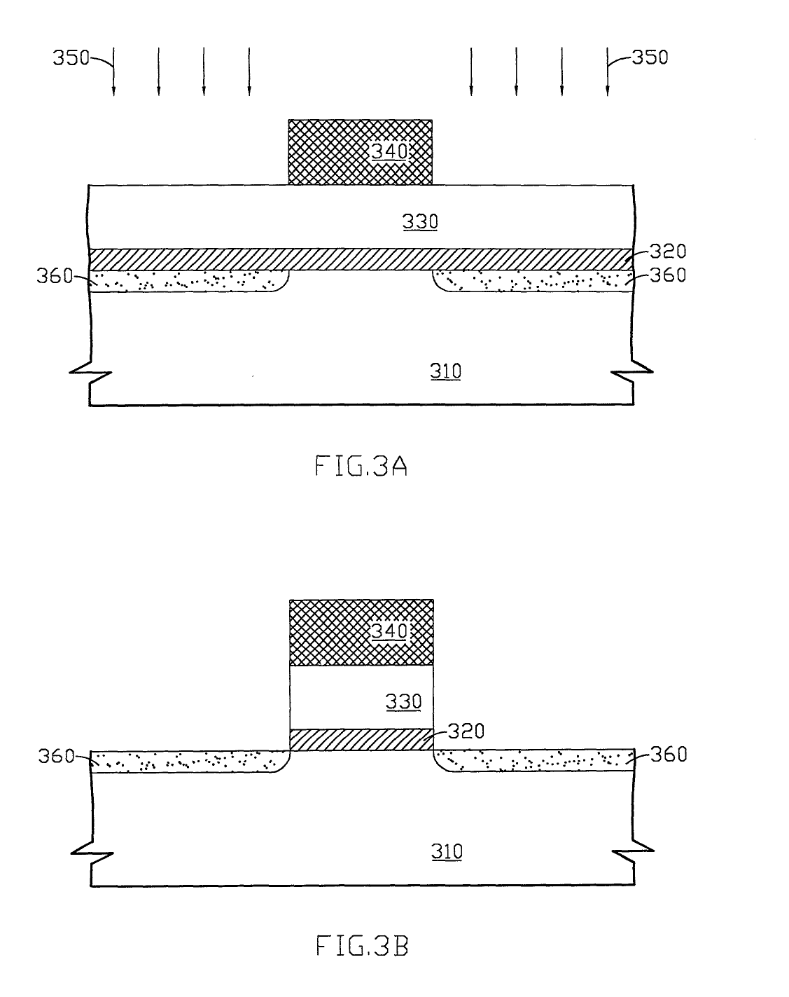

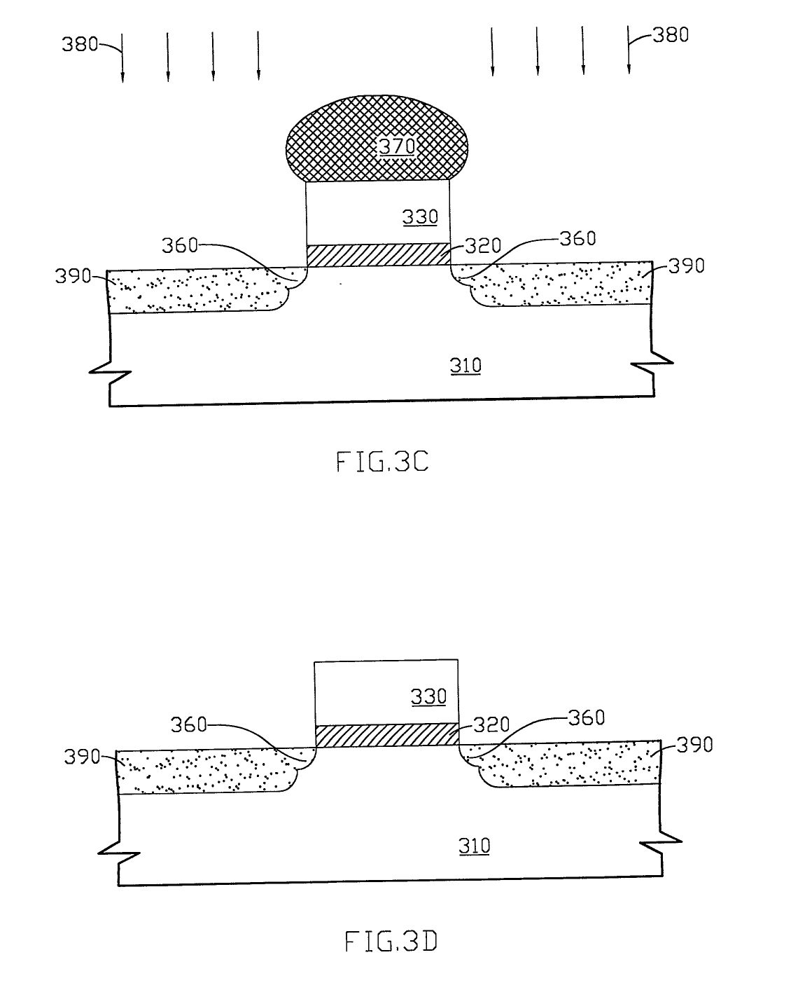

As illustrated in FIG. 3A, firstly, in this embodiment, a semiconductor substrate 310 is provided, and a gate oxide layer 320 is formed on said semiconductor substrate 310. Next, a poly film 330 is deposited on said gate oxide layer 320, and a photo-resist 340 is formed on the poly film 330 for defining a length of poly gate, wherein the profile of the photo-resist 340 will be influenced by temperature change. Then, proceeding with an ion implant 350 of the lightly doped drain (LDD) through poly film 330 into the structure of above by the photo-resist 340 as a mask, so as to form a lightly doped drain region 360 in the semiconductor substrate 310. Then, the poly film 330 is etched to form a poly gate 330, as shown in FIG. 3B.

Referring to FIG. 3C, in this embodiment, because the profile of the photo-resist 340 will expand when raising the temperature. Hence, the profile of the photo-resist 340 can be controlled by thermal process at above 150° C., so as to form a photo-resist 340 which is more wider than width of poly gate 330. Next, an ion implant 380 of the source/drain is carried out into the semiconductor substrate 390 by the photo-resist 370 as a mask. Afterward, the photo-resist 370 is removed. Finally, a rapid thermal process (RTP) is carried out to form the source/drain region 390 in the semiconductor substrate 310, as shown in FIG. 3D.

In this embodiment of the present invention, the short channel effect is reduced by means of forming ultra-shallow junctions. The lightly doped drain through an ion-implanted buffer layer can avoid channeling tails that penetrate relatively deeply into the silicon substrate or implanted junctions. The present invention is also able to perform the source/drain implant without forming spacers by single mask. Hence, the method of the present invention can simplify step of the conventional process, and it is able to correspond to economic effect.

This invention can provide a material of RELACS which reacts with photo-resist to form a new photo-resist-relacs by RELACS process. This photo-resist-relacs can substitute spacers as an ion implanted mask of the source/drain regions, and it is able to control the depth of junction shallow enough and exactly. Thus, good shallow junctions integrity can be formed on silicon substrate. The RELACS process of above makes use of thermal crosslinking reaction with the acid existed on thep photo-resist, wherein the material of RELACS should be consist of water soluble resin and crosslinker.

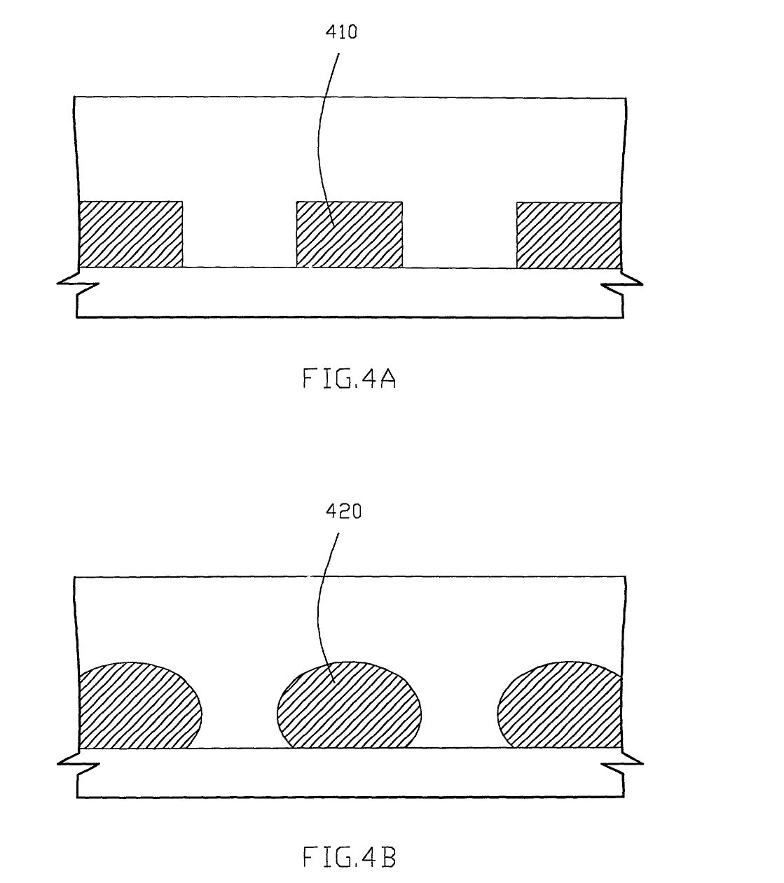

This present invention can also change the profile of the photo-resist by controlling the temperature, so as to substitute spacers as an ion implanted mask of the source/drain regions. The image of the photo-resist material 410 is at room temperature as shown in FIG. 4A. The photo-resist material 410 will expand to form a photo-resist material 420, as shown in FIG. 4B, whose profile is more wider than photo-resist material 410 when the photo-resist material 410 is baked at about 150° C. to 160° C. Hence, it is able to reach to purpose that economize on cost. Method of the present invention is the best semiconductor compatible process for deep sub-micro process.

Obviously, many modifications and variations of the present invention are possible in light of the above teachings. It is therefore to be understood that within the scope of the appended claims, the present invention may be practiced otherwise than as specifically described herein.

Although specific embodiments have been illustrated and described, it will be obvious to those skilled in the art that various modifications may be made without departing from what is intended to be limited solely by the appended claims.

What is claimed is:

1. A method for forming a semiconductor device having shallow junctions, comprising:
providing a semiconductor substrate;
forming an oxide layer on said semiconductor substrate;
forming an ion-implanted buffer layer on said oxide layer;
forming and defining a photo-resist layer on said ion-implanted buffer layer;
performing with an ion implant through said ion-implanted buffer layer into said semiconductor substrate by said photo-resist layer to form an ion-implanted region; and
performing the follow-up process to form a device.

2. The method according to claim 1, wherein said ion-implanted region is a doped drain region.

3. A method for forming a semiconductor device having shallow junctions, comprising:
providing a semiconductor substrate;
forming an oxide layer on said semiconductor substrate;
forming an ion-implanted buffer layer on said oxide layer;
forming and defining a first photo-resist layer on said ion-implanted buffer layer;
performing a first ion implant through said ion-implanted buffer layer into said semiconductor substrate by said first photo-resist as a ion-implanted mask to form a first ion-implanted region;
etching said ion-implanted buffer layer on said semiconductor substrate by said first photo-resist layer as an etched mask to form a gate on said semiconductor substrate;
coating a material of relacs on said first photo-resist, and said material of relacs reacts with first photo-resist to form a second photo-resist on said gate;
removing said second photo-resist layer on said gate; and
forming a second ion-implanted region in said semiconductor substrate.

4. The method according to claim 3, wherein said first ion-implanted region is a doped drain having a concentration less than that of the second ion implant region.

5. The method according to claim 3, wherein said second photo-resist layer is a chemical compound of said first photo-resist.

6. The method according to claim 3, wherein said second photo-resist layer is formed by relacs process.

7. The method according to claim 3, wherein said second photo-resist layer is more dimensional than first photo-resist layer.

8. The method according to claim 3, wherein said second ion-implanted region is formed by proceeding a second ion implant to said semiconductor substrate and using said second photo-resist layer as a mask.

9. The method according to claim 3, wherein said second ion-implanted region is a source/drain region.

10. The method according to claim 3, wherein the step for forming said second ion-implanted region comprises a thermal process.

11. A method for forming a semiconductor device having shallow junctions, comprising:
providing a semiconductor substrate;
forming an oxide layer on said semiconductor substrate;
forming an ion-implanted buffer layer on said oxide layer;
forming and defining a first photo-resist layer on said ion-implanted buffer layer;
performing a first ion implant through said ion-implanted buffer layer into said semiconductor substrate by said first photo-resist as a ion-implanted mask to form a first ion-implanted region.
etching said ion-implanted buffer layer on said semiconductor substrate by said first photo-resist layer as a etched mask to form a gate on said semiconductor substrate;
performing a thermal process with said first photo-resist layer on said gate to form a second photo-resist layer;
removing said second photo-resist layer on said gate; and
forming a second ion implant region in said semiconductor substrate.

12. The method according to claim 11, wherein said first ion implant region is lightly doped drain.

13. The method according to claim 11, wherein said second ion implant region is formed by proceeding a second ion implant into said semiconductor substrate and using said second photo-resist layer as a mask.

14. The method according to claim 11, wherein said second photo-resist layer is formed by thermal changing profile of said first photo-resist layer.

15. The method according to claim 11, wherein said second photo-resist layer is more dimensional than first photo-resist layer.

16. The method according to claim 11, wherein said second ion-implanted region is formed by proceeding a second ion implant to said semiconductor substrate and using said second photo-resist layer as a mask.

17. The method according to claim 11, wherein the step for forming said second ion-implanted region comprises a thermal process.

18. A method for forming a semiconductor device having shallow junctions, comprising:
providing a semiconductor substrate;
forming a gate oxide layer on said semiconductor substrate;
forming a poly film on said gate oxide layer;
forming a first photo-resist layer on said poly film;
performing a ion implant of the lightly doped drain through said poly film by said first photo-resist layer as a mask, so as to form a lightly doped drain region in said semiconductor substrate;
forming a gate on said semiconductor substrate;
performing a dimensional expanding process to form a second photo-resist layer by adding the width of said first photo-resist layer;
performing a ion implant of the source/drain into said semiconductor substrate by said second photo-resist layer as a mask, so as to form a second ion implant region in said semiconductor substrate; and
removing said second photo-resist layer on said gate.

19. The method according to claim 18, wherein said dimensional expanding process comprises a thermal process.

20. The method according to claim 18, wherein said dimensional expanding process comprises a relacs process.
